(19) United States
(12) Patent Application Publication
(10) Pub. No.: US 2016/0185470 A1
(43) Pub. Date: Jun. 30, 2016

(54) DEVICE FOR THE RECOVERY OF THERMAL ENERGY DISSIPATED BY A SATELLITE IN A VACUUM

(71) Applicant: AIRBUS GROUP SAS, BLAGNAC (FR)

(72) Inventor: Jean-Francois GENESTE, TOULOUSE (FR)

(21) Appl. No.: 14/984,832

(22) Filed: Dec. 30, 2015

(30) Foreign Application Priority Data
Dec. 31, 2014 (EP) 14307224.7

(51) Int. Cl. B64G 1/66; H01L 35/30; B64G 1/58

(52) U.S. Cl. CPC B64G 1/66; B64G 1/58; H01L 35/30

(57) ABSTRACT

A device for the recovery of a proportion of the energy which is dissipated, by the Joule effect, by the equipment of a predetermined satellite in a vacuum atmosphere, includes at least one radiative panel (10) which is designed to permit the cooling of the satellite (20) payload, and a thermoelectric generator, the heat source (12) of which is supplied with infrared photons by the radiative panels (10), whereby the latter are configured to concentrate the infrared photons towards the heat source (12).

### FIELD OF THE INVENTION

The present invention relates, in general, to the field of space vehicles. More specifically, it relates to power supply devices in said space vehicles.

More specifically still, the invention relates to a device for the recovery of heat energy dissipated by a space vehicle.

### PRIOR ART

Satellites, for example telecommunication satellites, require a substantial quantity of electrical energy to power their payload.

Conventionally, space vehicles in terrestrial orbit, such as satellites, are supplied with energy by means of panels of photovoltaic cells. These cells, for example of gallium arsenide construction, deliver an efficiency of the order of 30%. The cost of these cells is extremely high and, in the complete satellite, the budget for photovoltaic panels may be as high as 20% of the total cost of the satellite. These panels are also fragile, and their efficiency declines over the service life of the satellite.

### DESCRIPTION OF THE INVENTION

To this end, the invention relates firstly to a device for the recovery of a proportion of the energy which is dissipated, by the Joule effect, by the equipment of a predetermined satellite in a vacuum atmosphere, this recovery device comprising radiative panels which are designed to permit the cooling of the satellite payload, and a thermoelectric generator, the heat source of which is supplied with infrared photons by the radiative panels, whereby the latter are configured to concentrate said infrared photons towards said heat source.

It is known that the heat dissipated by the electronic equipment of the satellite accounts for approximately four-fifths of the electrical energy consumed by this equipment. This heat must be discharged into space in order to prevent the overheating of the satellite. It is therefore sensible to recover a proportion of this dissipated heat in order to generate further electrical energy, thereby reducing the need to supply solar radiation to the satellite and, for example, reducing the surface area of photovoltaic panels required.

The invention employs radiative panels which are used for the cooling of the satellite (at relatively low temperatures of the order of 80° C.), oriented in a direction facing away from the sun, in order to concentrate and transfer heat towards the heat source (at a temperature significantly in excess of 80° C.) of an electric power supply device, for example of the thermoacoustic generator type. This transmission may appear paradoxical, as it is the cold source which will heat the heat source.

Recently, a certain number of publications have described an alternative to conventional solar panels for satellites, based upon thermoelectric systems which involve the conversion of solar radiation into heat, and of heat into electricity. Amongst these options, the thermoacoustic motor has attracted the attention of the European Space Agency.

Furthermore, in high-power satellites, particularly telecommunication satellites, losses by the Joule effect may be substantial, up to 80%. The recovery of this energy, which is customarily lost, is therefore a major factor in the reduction of the size of solar panels, the surface area of which invariably comes at the cost of complexity and weight. Nevertheless, in an efficient thermoelectric system, for reasons associated with the efficiency of the Carnot cycle, the temperature of the heat source is extremely high, sometimes in excess of 1000° C.

Unfortunately, losses by the Joule effect occur at substantially lower temperatures, of the order of 80° C. Consequently, in accordance with the second law of thermodynamics, it is potentially not possible to recover heat emitted at a temperature of 80° C. from a heat source at 1000° C. However, conditions in space, and particularly conditions in a vacuum, in which thermal exchanges can only be completed by radiation, permit the second law to be “bent” to a certain degree, thereby permitting, under these very specific conditions, the passive heating of a heat source by means of a cold source.

This is the highly specific issue which the invention proposes to resolve, for example as described hereinafter with reference to an example of a telecommunication satellite.

In one particular embodiment, at least one radiative panel is configured in the form of a surface, one side of which is radiative, whereas the other side is insulated, specifically for the prevention of radiation towards the body of the satellite, whereby the radiative panel is curved such that the highest possible proportion of the photons emitted by said radiative panel converge towards a predetermined zone of space opposite said radiative panel.

In various embodiments, which may be applied in conjunction, where technically possible:
the radiative panel is configured in the form of a substantially rectangular surface, curved around a longitudinal axis X such that it shows a parabolic cross section perpendicularly to this longitudinal axis X.
the radiative panel is configured in the form of a series of stackable and articulated connected plane surfaces which are arranged, when deployed, in approximation to a parabolic cylinder.
the heat source is arranged in the focal zone of the rays emitted by the emitter surface of the radiative panel, this heat source being thermally insulated, except at an input zone of the thermal radiation received from the radiative panel.

The cold source, as a result of its solid viewing angle, perceives deep space, of which the heat source represents only a tiny part. Under these conditions, the average temperature perceived by the latter will be lower than its own temperature, and it will therefore emit infrared radiation, the focal point of which will be the heat source. Said heat source itself will have a solid viewing angle which will perceive an average background temperature which is lower than its own temperature and, in consequence, will also act as an emitter. As the emissions are proportional to the surface areas, in accordance with the well-known laws of thermodynamics, if exchanges are to proceed in the direction of heating of the heat source, it is necessary for the emission surface of the latter to be in a ratio with that of the cold source which is equal to the ratio of the temperatures of the two sources to the power of 4. Even if such a ratio of surface areas is technically feasible, the invention will permit the substantial reduction of the latter.
the device for the recovery of dissipated heat comprises a refractive concentrator, arranged at the focal point of the radiative panel, which directs the rays received towards the heat source.
the heat source is arranged behind the radiative panel.
the device comprises an optical concentrator which is perpendicular to said input zone.
the optical concentrator, facing the radiation received, is configured with a convergent surface, which is symmetrical in relation to a vertical axis Z.
the convergent surface is a curved surface free of angles such that, at any point along said convergent surface, an incident ray received in the vertical axis Z is directed towards the throat of the convergent surface.
in the case where the radiative panel is of the parabolic cylinder type, with a directrix arranged in a longitudinal axis X, the convergent surface is formed of two half-surfaces of the parabolic cylinder type.
the perpendicular cross section of the convergent surface is formed of rectilinear segments, approximating to a parabola.
the optical concentrator, facing the radiation received, is configured with a concentrating surface which simultaneously serves to concentrate the incident rays towards the input zone, and to reject towards said input zone rays emitted radially by the heat source. Refractive concentrators of this type are generally provided with smooth and reflective surfaces.
the perpendicular cross section of the concentrating surface for the invention is formed of a series of segments, in a zig-zag arrangement converging towards the input zone, whereby the profile of this cross section is such that the infrared rays emitted by the heat source, in the greatest proportion of the solid angle of emission, strike a part of the concentrating surface which forms a localized reflector towards the input zone and, conversely, the infrared rays originating from the radiative panel are reflected on successive walls, the angles of which are configured such that any incident ray in the vertical axis Z is directed towards the throat of the concentrating surface. Where applicable, the segments will be curved to the same localized curvature as that of a smooth concentrator.
the thermoelectric generator is of the thermoacoustic type.

In one particular embodiment, the device comprises a combination of the following in the heat source:
firstly, an input zone which is designed for the reception of the infrared rays emitted by the radiative panel(s), and
secondly, a second input zone which is designed for the reception of solar radiation which has been concentrated by the primary concentrator, whereby the direction Z, opposite which the radiative panel is arranged, is substantially oriented at 90° to the direction of origin of the solar radiation.

Secondly, the invention relates to a satellite, comprising a device of the type disclosed above.

In the particular case where the satellite is supplied with electrical energy by a thermoacoustic generator, the heat source of the device for the recovery of heat dissipated by the radiative panel is combined with the heat source of the primary thermoacoustic generator.

### DESCRIPTION OF THE FIGURES

The description which follows, which is provided solely by way of an example of one embodiment of the invention, refers to the attached figures, in which:

FIG. 1 shows a schematic representation of the key elements implemented in the invention,

FIG. 2 illustrates, also in a schematic representation, a refractive radiation concentrator used in one example of implementation of the invention,

FIG. 3 illustrates, in a similar representation, a second radiation concentrator, employed in a variant of the implementation of the invention,

FIG. 4 illustrates a front view, a side view and a perspective view of one of the potential configurations of a satellite in which electricity is generated by a thermoacoustic motor.

### DETAILED DESCRIPTION OF ONE EMBODIMENT OF THE INVENTION

The invention is intended for implementation in a high-vacuum environment, of the type which exists in terrestrial orbit or, more generally, between astral bodies. Under these vacuum conditions, it is known that the transfer of heat between two distant bodies proceeds by radiation only.

The invention, for example, finds its place as part of a space vehicle, such as a satellite in terrestrial orbit or a probe.

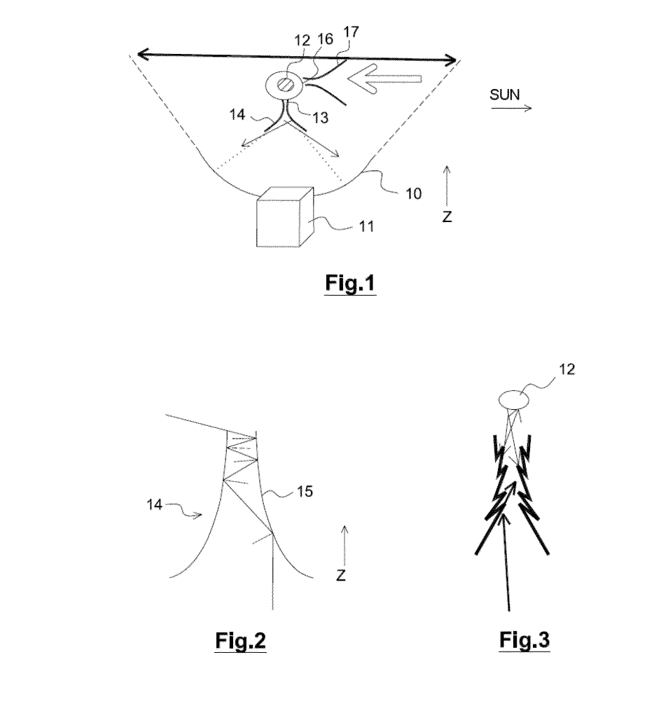

As shown in FIG. 1, a device for the recovery of heat dissipated by the payload of the satellite comprises firstly, in the present exemplary embodiment, at least one radiative panel 10 attached to the body 11 of the satellite, represented here schematically, and for purely illustrative purposes, by a simple cube. It is clear that the device may comprise any given number of radiative panels 10, according to the requirements or constraints of the satellite on which they are installed. These radiative panels 10 are preferably oriented in a direction not facing the sun, in order to enhance their efficiency of cooling. They are oriented here, for example, at 90° to the direction of the sun.

Each radiative panel 10 is presumed to be connected to the dissipative payload of the satellite by means which are known per se, for example heat pipes, and which, as such, fall outside the scope of the present invention. It is simply accepted here that the heat dissipated by said dissipative equipment is transferred to the radiative panel 10, the function of which is to radiate heat towards space in the form of infrared photons.

The constituent materials of the radiative panel 10 are presumed to be known per se, as is its internal architecture. The design of these materials and this architecture are such that the radiative panel 10 emits infrared photons in a primary direction. In the present exemplary embodiment, the radiative panel is configured in the form of a curved surface, one side of which is radiative, whereas the other side is insulated, specifically for the prevention of radiation towards the body of the satellite which is intended to be cooled.

In the present exemplary embodiment, which is not provided by way of limitation, the radiative panel 10 is curved such that the highest possible proportion of photons emitted by said radiative panel 10 converge towards a predetermined zone of space opposite said radiative panel 10. In the example illustrated in FIG. 1, the radiative panel 10 is configured in the form of a substantially rectangular surface, curved around a longitudinal axis X such that it shows a parabolic cross section perpendicularly to this longitudinal axis X. It therefore constitutes a parabolic cylinder. Accordingly, the photons emitted by the radiative panel 10 will naturally converge towards the line forming the focal point of the parabola, along the longitudinal axis X.

In non-limiting variant embodiments, the radiative panel may be configured in the form of a paraboloid of revolution around the vertical axis Z, or alternatively of a torus of parabolic cross section. In the first case, the focal zone is substantially of the point type. In the second case, the focal zone is a circle situated opposite the torus.

In a further variant embodiment, the radiative panel 10 is configured in the form of a series of articulated connected plane surfaces which are arranged, when deployed, in approximation to a parabolic cylinder. An arrangement of this type is advantageous for the purposes of the storage of such a radiative panel during the launch of the satellite, in the form of a stack of articulated surfaces.

A heat source 12, arranged in the focal zone of the rays emitted by the emitter surface of the radiative panel, will naturally be heated by the effect of the infrared radiation emitted by the radiative panel 10 and concentrated at this point. This heat source 12 is presumed to be completely thermally insulated, except at an input zone 13 of the thermal radiation received from the radiative panel, said input zone 13 being arranged here opposite the radiative panel 10. In this way, the heat source 12 acts as an isolated black body.

Alternatively, the device for the recovery of dissipated heat comprises firstly a secondary reflector, arranged at the focal point of the radiative panel (in place of the heat source 12 illustrated in FIG. 1), and which directs the rays received towards the heat source 12, whereby the latter, for example, is then arranged behind the radiative panel 10.

In order to reduce the losses of heat from the heat source 12 towards the radiative panel 10 at the level of the input zone 13, the dimensions of this input zone 13 are reduced, and the device comprises, in the present exemplary embodiment and perpendicular to said input zone 13, an optical concentrator 14, the cross section of which is shown more clearly in FIG. 2.

As shown in this figure, which is provided by way of a non-limiting exemplary embodiment, the optical concentrator 14, facing the radiation received, is configured with a convergent surface 15, which is symmetrical in relation to a vertical axis Z. In this case, this convergent surface 15 is a curved surface free of angles such that, at any point along said convergent surface 15, an incident ray received in the vertical axis Z is reflected (or refracted) towards the throat of the convergent surface 15.

In the case where the radiative panel 10 is of the parabolic cylinder type, with a directrix arranged in a longitudinal axis X, the convergent surface will be formed of two half-surfaces of the parabolic type.

In the case where the radiative panel is of the paraboloid of revolution type, the convergent surface shows a symmetry of revolution around the vertical axis Z.

In the case of a radiative panel of the torus type with a parabolic cross section, the convergent surface may advantageously be configured with a toric surface of revolution, with a cross section of the type described above.

FIG. 2 illustrates the path of an incident ray of light in the vertical axis Z, which is reflected a number of times on the two symmetrical surfaces of the convergent surface 15, thereby progressing towards the throat of said convergent surface 15.

In one variant embodiment (not illustrated in the figures), the perpendicular cross section of the convergent surface 15 is formed of rectilinear segments, approximating to a hyperbola.

In a further variant embodiment, the convergent surface 15 is replaced by a concentrating surface 15′, which simultaneously serves to concentrate the incident rays towards the input zone 13, and to reject towards said input zone 13 rays emitted radially by the heat source 12.

To achieve this aim, the concentrating surface is configured with a cross section illustrated by way of non-limiting example in FIG. 3.

As shown in this figure, the perpendicular cross section of the concentrating surface 15′ is formed of a series of segments, where applicable “of the hyperbolic type”, in a zig-zag arrangement converging towards the input zone 13. The profile of this cross section is such that the infrared rays emitted by the heat source 12, in the greatest proportion of the solid angle of emission, strike a part of the concentrating surface 15′ which forms a localized reflector towards the input zone 13. Conversely, the infrared rays originating from the radiative panel 10 are reflected on successive walls, the angles of which are configured such that any incident ray in the vertical axis Z is directed towards the throat of the concentrating surface 15′. Ultimately, the device is conducive to the receipt of energy from the radiative panel, in the form of infrared photons, which exceeds that emitted by the heat source, thereby permitting a surface area ratio which is more easily achievable than by the simple application of the laws of thermodynamics.

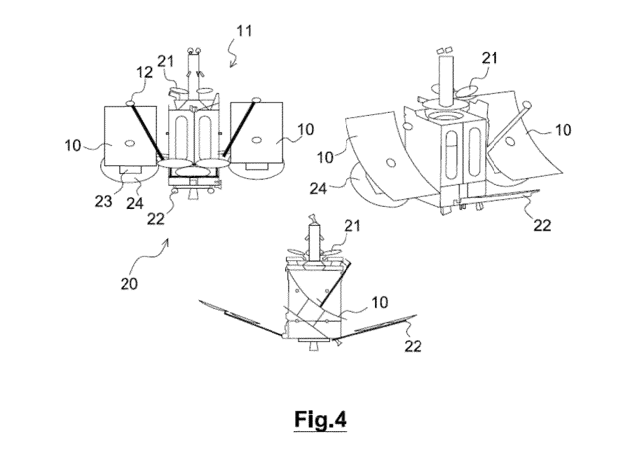

In FIG. 4, the concentrating surface 15′ comprises about ten segments on either side. It is clearly possible, as a variant, to employ a higher or lower number of segments. Likewise, these rectilinear segments may be replaced by curved lines, such as segments of a parabola and/or a hyperbola.

The heat recovery device is completed by an electric generator (not illustrated in the figures), which is designed for the transformation of thermal energy into electrical energy, for example a generator of the thermoacoustic type, which is known per se.

In the particular case where the satellite is supplied with electrical energy by a thermoacoustic generator, the heat source 12 of the device for the recovery of heat dissipated by the radiative panel 10 may be combined with the heat source of the primary thermoacoustic generator.

Likewise, and as illustrated in FIG. 1 as already indicated, it is possible in one variant embodiment to combine the following in the heat source 12:
firstly, an input zone 13 which is designed for the reception of the infrared rays emitted by the radiative panel(s) 10, and
secondly, a second input zone 16 which is designed for the reception of solar radiation which has been concentrated by a second concentrator 17.

As seen then in said FIG. 1, the direction Z, opposite which the radiative panel 10 is arranged, is substantially oriented at 90° to the direction of origin of the solar radiation originating from the concentration device which constitutes the primary energy source.

FIG. 4 shows a simplified illustration of a possible configuration of a satellite equipped with a device for the generation of electricity by solar concentration.

This figure shows a satellite 20, the body 11 of which, in this case, carries a series of equipment 21, 22. The body 11 is attached to two reflective panels situated on either side of said body 11. In this case, these reflective panels are configured as a parabolic cylinder. Here, they are arranged facing the sun.

In this case, each reflective panel is shown attached to a motor unit 23, which itself is attached to a cold radiator of the motor 24.

In this case, the reflective panels are arranged opposite secondary reflectors 24, represented here in the form of two zones in point form. These secondary reflectors 24 direct the radiation received towards heat sources, arranged behind the reflective panels, whereby the latter are provided with a central opening for the passage of this concentrated radiation.

### MODE OF OPERATION

If the device for the recovery of dissipated heat is to operate, it is necessary that the radiation emitted by the heat source 12 via the input zone 13 remains lower than the radiation received from the radiative panels 10 through this same input zone 13. This condition is fulfilled, in the case considered here, by way of for purely illustrative example, of a temperature of the heat source 12 of 1000° C. and of a radiative panel 10 at 100° C., if the surface area ratio between the radiative panel 10 and the input zone 13 of the heat source 12 is greater than approximately 135. In the case where the device comprises a concentric surface 15′ which is liable to direct a substantial proportion of the rays emitted by the heat source 12 towards the latter, on the grounds of emission which, by definition, is isotropic, this surface area ratio will be significantly reduced.

By way of an example of use, assuming the case of a satellite which consumes 5 kW of electrical energy and is used for the generation of electricity, the surface area of the panels may be roughly estimated at 12 m², if these panels have an efficiency of 30% and the solar radiation is estimated at 1.3 kW/m².

Assuming then that the satellite generates 4 kW in the form of heat due to the Joule effect, and that it is capable of emitting 2 kW by means of its radiative panels 10, with the installation of a device for the recovery of dissipated heat, as described above, the surface area of the panels required to supply power to the satellite is reduced to 10 m². The resulting saving in surface area is therefore of the order of 20%. For high-power applications, savings in surface area, and particularly in mass, will therefore be substantial.

1. Device for the recovery of a proportion of the energy which is dissipated, by the Joule effect, by the equipment of a predetermined satellite in a vacuum atmosphere, wherein the recovery device comprises at least one radiative panel which is designed to permit the cooling of the satellite payload, and a thermoelectric generator, the heat source of which is supplied with infrared photons by the radiative panels, whereby the latter are configured to concentrate said infrared photons towards said heat source.

2. Device for the recovery of thermal energy according to claim 1, wherein at least one radiative panel is configured in the form of a surface, one side of which is radiative, whereas the other side is insulated, specifically for the prevention of radiation towards the body of the satellite, whereby the radiative panel is curved such that the highest possible proportion of the photons emitted by said radiative panel converge towards a predetermined zone of space opposite said radiative panel.

3. Device for the recovery of thermal energy according to claim 2, wherein the radiative panel is configured in the form of a substantially rectangular surface, curved around a longitudinal axis X such that it shows a parabolic cross section perpendicularly to this longitudinal axis X.

4. Device for the recovery of thermal energy according to claim 2, wherein the radiative panel is configured in the form of a series of stackable and articulated connected plane surfaces which are arranged, when deployed, in approximation to a parabolic cylinder.

5. Device for the recovery of thermal energy according to claim 2, wherein the heat source is arranged in the focal zone of the rays emitted by the emitter surface of the radiative panel, this heat source being thermally insulated, except at at least one input zone of the thermal radiation received from the radiative panel.

6. Device for the recovery of thermal energy according to claim 2, wherein the device for the recovery of dissipated heat comprises a secondary reflector, arranged at the focal point of the radiative panel, which directs the rays received towards the heat source.

7. Device for the recovery of thermal energy according to claim 6, wherein the heat source is arranged behind the radiative panel.

8. Device for the recovery of thermal energy according to claim 5, wherein the device comprises an optical concentrator which is perpendicular to said input zone.

9. Device for the recovery of thermal energy according to claim 8, wherein the optical concentrator, facing the radiation received, is configured with a convergent surface, which is symmetrical in relation to a vertical axis Z.

10. Device for the recovery of thermal energy according to claim 9, wherein the convergent surface is a curved surface free of angles such that, at any point along said convergent surface, an incident ray received in the vertical axis Z is directed towards the throat of the convergent surface.

11. Device for the recovery of thermal energy according to claim 10, designed for the case where the radiative panel is of the parabolic cylinder type, with a directrix arranged in a longitudinal axis X, wherein the convergent surface is formed of two half-surfaces of the parabolic cylinder type.

12. Device for the recovery of thermal energy according to claim 9, wherein the perpendicular cross section of the convergent surface is formed of rectilinear and/or curved segments, approximating to a parabola.

13. Device for the recovery of thermal energy according to claim 8, wherein the optical concentrator, facing the radiation received, is configured with a concentrating surface which simultaneously serves to concentrate the incident rays towards the input zone, and to reject towards said input zone rays emitted radially by the heat source.

14. Device for the recovery of thermal energy according to claim 13, wherein the perpendicular cross section of the concentrating surface is formed of a series of segments, in a zig-zag arrangement converging towards the input zone, whereby the profile of this cross section is such that the infrared rays emitted by the heat source, in the greatest proportion of the solid angle of emission, strike a part of the concentrating surface which forms a localized reflector towards the input zone and, conversely, the infrared rays originating from the radiative panel are reflected on successive walls, the angles of which are configured such that any incident ray in the vertical axis Z is directed towards the throat of the concentrating surface.

15. Device for the recovery of thermal energy according to claim 1, wherein the thermoelectric generator is of the thermoacoustic type.

16. Device for the recovery of thermal energy according to claim 15, wherein it comprises a combination of the following in the heat source:
firstly, an input zone which is designed for the reception of the infrared rays emitted by the radiative panel(s), and
secondly, a second input zone which is designed for the reception of solar radiation which has been concentrated by a second concentrator,
whereby the direction Z, opposite which the radiative panel is arranged, is substantially oriented at 90° to the direction of origin of the solar radiation.

17. Space vehicle, wherein it comprises a device for the recovery of thermal energy according to claim 1.

18. Space vehicle according to claim 17, wherein, in the particular case where the satellite is supplied with electrical energy by a thermoacoustic generator, the heat source of the device for the recovery of heat dissipated by the radiative panel is combined with the heat source of the primary thermoacoustic generator.
